(19) United States
(12) Patent Application Publication
(10) Pub. No.: US 2026/0246484 A1
(43) Pub. Date: Aug. 20, 2026

(54) MULTIPLE-BAND RF CHIP AND TRANSCEIVER INCLUDING THE SAME

(71) Applicant: SAMSUNG ELECTRONICS CO., LTD., Suwon-si (KR)

(72) Inventors: Taewoo YU, Suwon-si (KR); Junseong KIM, Suwon-si (KR); Junseuk SUH, Suwon-si (KR); Kyungwoo YOO, Suwon-si (KR); Hyung Sun LIM, Suwon-si (KR); Dooseok CHOI, Suwon-si (KR); Joonhoi HUR, Suwon-si (KR)

(73) Assignee: SAMSUNG ELECTRONICS CO., LTD., Suwon-si (KR)

(21) Appl. No.: 19/457,634

(22) Filed: Jan. 23, 2026

(30) Foreign Application Priority Data
Feb. 18, 2025 (KR) 10-2025-0021133

(51) Int. Cl. H04B 1/04; H04B 1/40

(52) U.S. Cl. CPC H04B 1/04; H04B 1/40

(57) ABSTRACT

A radio-frequency (RF) chip includes a first switch, a first frequency multiplier and a first power amplifier. The first switch includes a single first pole coupled to a single transmission path provided with a local oscillator (LO) signal and a plurality of second poles coupled to a plurality of transmission paths, and configured to couple the single first pole to one of the plurality of second poles based on switching. The first frequency multiplier is coupled to a first transmission path among the plurality of transmission paths, and configured to perform frequency multiplication based on a first multiplication factor. The first power amplifier is coupled to the first frequency multiplier.

### CROSS-REFERENCE TO RELATED APPLICATION(S)

This U.S. non-provisional application claims priority under 35 USC § 119 to Korean Patent Application No. 10-2025-0021133, filed on Feb. 18, 2025, in the Korean Intellectual Property Office, the disclosure of which is herein incorporated by reference in its entirety.

### BACKGROUND

The present disclosure relates to a multiple-band RF chip and a transceiver including the same.

With the advancement in wireless communication technology, the importance of radio-frequency (RF) chips designed to operate across various frequency bands is increasing. RF chips according to the related arts were often designed to operate in a specific frequency band. However, in environments in which various wireless communication technologies coexist, such as frequency-modulated continuous wave (FMCW) radar, nth-generation mobile communications, Wi-Fi, Bluetooth, or satellite communication, RF chips designed to operate in multiple frequency bands are required.

For example, in the case of radar systems, various applications exist depending on a detection range to a target intended to be detected by the radar, or the like. In radar systems according to the related arts, there were methods of modifying or reconfiguring configurations such as parameters related to a local oscillator (LO) signal based on the application. However, simply modifying the configurations of a single LO signal has limitations in terms of available bandwidth of the signal. In addition, there are factors to be considered in a digital domain, such as register update and timing configurations, to modify a configuration of the LO signal.

### SUMMARY

The present disclosure provides a multiple-band RF chip configured to cover multiple bands with a single LO signal and a transceiver including the multiple-band RF chip.

According to an embodiment, a radio-frequency (RF) chip includes a first switch comprising a single first pole coupled to a single transmission path provided with a local oscillator (LO) signal and a plurality of second poles coupled to a plurality of transmission paths, the first switch configured to couple the single first pole to one of the plurality of second poles based on switching, a first frequency multiplier coupled to a first transmission path among the plurality of transmission paths, the first frequency multiplier configured to perform frequency multiplication based on a first multiplication factor, and a first power amplifier coupled to the first frequency multiplier.

According to an embodiment, a radio-frequency (RF) chip includes a power splitter coupled to a single transmission path provided with a local oscillator (LO) signal and to a plurality of transmission paths, the power splitter configured to perform power distribution from the single transmission path to the plurality of transmission paths, a first frequency multiplier coupled to a first transmission path among the plurality of transmission paths, the first frequency multiplier configured to perform frequency multiplication based on a first multiplication factor, and a first power amplifier coupled to the first frequency multiplier.

According to an embodiment, a transceiver includes a processor configured to process a digital signal, a radio-frequency (RF) chip configured to obtain a first transmit signal having a frequency equal to or multiplied from a local oscillator (LO) frequency based on the digital signal, to distribute the first transmit signal from a single transmission path to a plurality of transmission paths, and to output a second transmit signal based on frequency multiplication and power amplification for at least one of the plurality of transmission paths, and a plurality of antennas configured to transmit the second transmit signal.

### BRIEF DESCRIPTION OF DRAWINGS

FIG. 1 is a diagram illustrating a switching-based RF chip according to one or more embodiments.

FIG. 2 is a diagram illustrating a switching-based RF chip including a frequency multiplier configured in a single transmission path according to one or more embodiments.

FIG. 3 is a diagram illustrating a switch-based reception circuit according to one or more embodiments.

FIG. 4 is a diagram illustrating a power distribution-based RF chip according to one or more embodiments.

FIG. 5 is a diagram illustrating a power distribution-based RF chip including a frequency multiplier configured in a single transmission path according to one or more embodiments.

FIG. 6 is a diagram illustrating a reception circuit according to one or more embodiments.

FIG. 7 is a diagram illustrating a transceiver according to one or more embodiments.

FIG. 8 is a waveform diagram illustrating a transmission operation of the transceiver according to one or more embodiments.

FIG. 9 is a flowchart illustrating a method of operating a transceiver according to one or more embodiments.

FIG. 10 is a waveform diagram illustrating a transmission operation of the transceiver according to one or more embodiments.

FIG. 11 is a flowchart illustrating a method of operating a transceiver according to one or more embodiments.

FIG. 12 is a diagram illustrating a vehicle according to one or more embodiments.

### DETAILED DESCRIPTION

The following description with reference to the accompanying drawings is provided to assist in a comprehensive understanding of various embodiments of the present disclosure.

In the present disclosure, terms referring to electronic devices or RF-related components or products (for example, an antenna, an RF chip or an RF integrated circuit (RFIC), a power amplifier (PA), a low-noise amplifier (LNA), a mixer, an analog baseband (ABB) circuit, a frequency multiplier, or the like) are merely exemplary for ease of description, and the embodiments are not limited to these terms. For example, other terms having equivalent technical meanings may be used. For example, an RF chip may be replaced with an RF circuit or an RF module.

In the present disclosure, the coupling between Component A and Component B may include both physical and electrical connections therebetween.

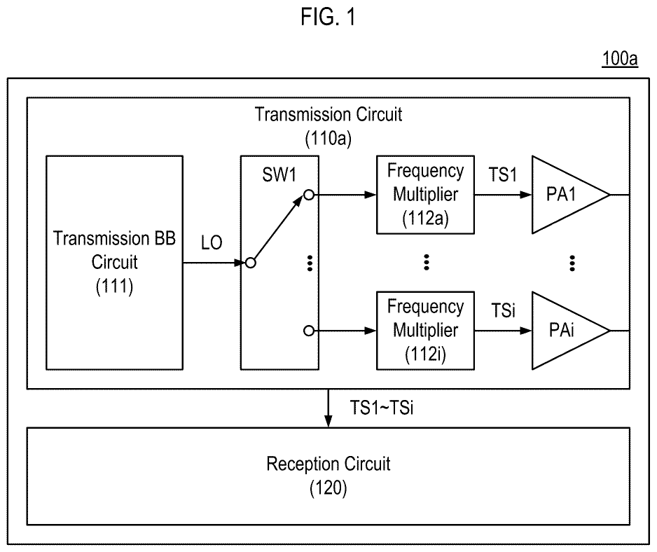

FIG. 1 is a diagram illustrating a switching-based RF chip according to one or more embodiments.

Referring to FIG. 1, an RF chip 100a according to one or more embodiments may include a transmission circuit 110a and a reception circuit 120.

The transmission circuit 110a may be configured to convert a transmit signal from a digital domain to an analog domain, and to process the transmit signal in the analog domain at the baseband as well as at frequency bands above the baseband. The transmission circuit 110a may include a transmission baseband circuit 111, a first switch SW1, a plurality of frequency multipliers 112a to 112i, and a plurality of power amplifiers PA1 to PAi.

The transmission baseband circuit 111 may be configured to convert a transmit signal from the digital domain to the analog domain, and to process the transmit signal in the analog domain at the baseband.

In one or more embodiments, the transmission baseband circuit 111 may include a digital-to-analog converter (DAC) for conversion into the analog domain, an analog baseband circuit for processing of the transmit signal at the baseband, a phase-locked loop (PLL) circuit, and an oscillator. The analog baseband circuit may be configured to perform at least one of signal amplification and gain control, buffering, filtering, power distribution, or providing an in-phase/quadrature (I/Q) path, on the transmit signal.

The PLL circuit may perform phase locking on a local oscillator (LO) frequency. For example, the PLL circuit may fix a phase of the transmit signal processed by the analog baseband circuit to the LO frequency. The LO frequency may be defined as a reference frequency. The oscillator may generate an LO signal LO having a fixed LO frequency and provide the LO signal to a first switch SW1.

The first switch SW1 may include a first terminal coupled to a single transmission path to which the LO signal is provided, and a plurality of second terminals coupled to a plurality of transmission paths. In the present disclosure, the term “a single transmission path” may refer to a path corresponding to or included in the transmission baseband circuit 111, which is configured to generate, obtain, and output a single LO signal. The term “a plurality of transmission paths” may refer to paths configured to process and output transmit signals between a plurality of antennas, not illustrated, coupled to the RF chip 110a and the plurality of second terminals. For example, the plurality of transmission paths may be configured as i paths (where i is a positive integer greater than or equal to 2). Therefore, the plurality of second terminals may also be configured as i terminals.

The first switch SW1 may couple a single first terminal and one of the plurality of second terminals based on switching. The switching enables the LO signal to be provided to the transmission path corresponding to one of the second terminals.

The plurality of frequency multipliers 112a to 112i may be configured to perform frequency multiplication on the transmit signal based on the same multiplication factor or different multiplication factors. In one or more embodiments, the plurality of frequency multipliers 112a to 112i may be configured as i terminals, corresponding to the i transmission paths. Based on the frequency multiplication, the frequency of the LO signal may be up-converted to a frequency multiplied by a multiplication factor.

Each frequency multiplier may be coupled to one of the plurality of transmission paths and performs frequency multiplication based on an assigned (defined or set) multiplication factor. For example, a first frequency multiplier may perform frequency multiplication on the LO signal provided to a single transmission path based on a multiplication factor M (where M is a positive integer greater than or equal to 2), and an ith frequency multiplier may perform frequency multiplication on the LO signal provided to another transmission path based on a multiplication factor N (where N is a positive integer, different from M, but also greater than or equal to 2). Accordingly, frequency-multiplied transmit signals having different center frequencies and bandwidths may be provided to each transmission path from a single common LO signal.

For example, when the frequency of the LO signal is denoted as fLO, the multiplication factor of the first frequency multiplier is denoted as M, and the multiplication factor of the ith frequency multiplier is denoted as N, then the frequency of the first transmit signal corresponding to the first transmission path may be M*fLO. In addition, the frequency of the ith transmit signal corresponding to the ith transmission path may be N*fLO. Similarly, when the bandwidth of the LO signal is denoted as BWLO, the bandwidth of the first transmit signal is denoted as BW1, and the bandwidth of the ith transmit signal is denoted as BWi, then BW1 is M*BWLO and BWi is N*BWLO.

The plurality of power amplifiers PA1 to PAi may be coupled to the plurality of frequency multipliers 112a to 112i. For example, the first power amplifier PA1 may be coupled to the first frequency multiplier 112a, and the ith power amplifier PAi may be coupled to the ith frequency multiplier 112i. The power amplifiers PA1 to PAi may perform power amplification on the frequency-multiplied transmit signals, respectively processed by the frequency multipliers.

The reception circuit 120 may be configured to process a receive signal in the analog domain at baseband and frequency bands above the baseband, and to convert the processed receive signal into the digital domain. In one or more embodiments, the reception circuit 120 may receive a plurality of transmit signals TS1 to TSi output from a plurality of frequency multipliers 112a to 112i included in the transmission circuit 110a and perform frequency down-conversion on a plurality of receive signals based on the plurality of transmit signals TS1 to TSi.

The RF chip 100a according to the above-described embodiments may provide a single LO signal LO to each transmission path through switching and perform frequency multiplication based on a multiplication factor assigned to each transmission path. Accordingly, the RF chip 100a according to the above-described embodiments may support various bandwidths using only a single LO signal LO without modifying configurations related to the LO signal LO, and the complexity and required area of the chip may be reduced as only one LO signal LO is used.

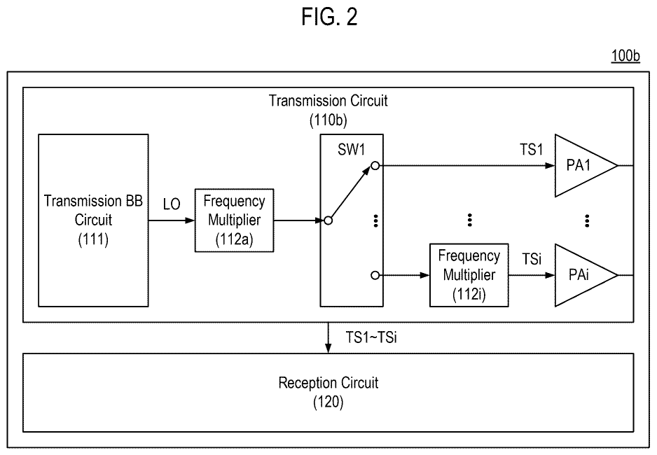

FIG. 2 is a diagram illustrating a switching-based RF chip including a frequency multiplier configured in a single transmission path according to one or more embodiments. Hereinafter, detailed descriptions of components that overlap with those previously described will be omitted for clarity and brevity.

Referring to FIG. 2, an RF chip 100b according to one or more embodiments may include a first frequency multiplier 112a configured in a single transmission path, and at least one frequency multiplier configured in a plurality of transmission paths.

The first frequency multiplier 112a may be configured in a single transmission path and perform frequency multiplication on the LO frequency based on a multiplication factor. The first frequency multiplier 112a may output the frequency-multiplied transmit signal to a single first pole of a first switch SW1. Unlike the illustration of FIG. 1, the first switch SW1 may provide a transmit signal having a multiplied frequency up-converted from the LO frequency to a single transmission path among a plurality of transmission paths.

In contrast to the RF chip of FIG. 1, which includes a frequency multiplier configured for each transmission path, the RF chip of FIG. 2 may include at least one frequency multiplier configured in a plurality of transmission paths. Accordingly, a frequency multiplier may not be configured in at least one transmission path among the plurality of transmission paths. For example, a frequency multiplier may not be configured in the first transmission path in which the first power amplifier PA1 is configured. The first power amplifier PA1 may amplify the transmit signal provided through the first switch SW1.

In contrast to the first transmission path, an ith transmission path including an ith power amplifier PAi may include a second frequency multiplier 112i. The second frequency multiplier 112i may perform frequency multiplication on a transmit signal provided through the first switch SW1 based on a multiplication factor.

For example, when a multiplication factor of the first frequency multiplier 112a is denoted as M and a multiplication factor of the second frequency multiplier 112i is denoted as N (where M and N are positive integers that are the same or different), then the frequency of the first transmit signal provided to the first power amplifier PA1 may be M*fLO. In addition, the frequency of the ith transmit signal provided to the ith power amplifier PAi may be M*N*fLO. Similarly, when the bandwidth of the LO signal LO is denoted as BWLO, the bandwidth of the first transmit signal is denoted as BW1, and the bandwidth of the ith transmit signal is denoted as BWi, then BW1 is M*BWLO and BWi is M*N*BWLO. Accordingly, BWi is different from BW1 by an integer multiple.

According to above-described the embodiments, the transmission circuit may provide the first transmit signal, multiplied by a factor of M, directly to the power amplifier (for example, in the first transmission path) or may further multiply the first transmit signal by a factor of N.

The reception circuit 120 may receive a plurality of transmit signals TS1 to TSi from a plurality of transmission paths and may perform frequency down-conversion on a plurality of receive signals based on the plurality of transmit signals TS1 to TSi.

The RF chip according to above-described the embodiments may support various bandwidths using only a single LO signal LO without modifying configurations related to the LO signal LO.

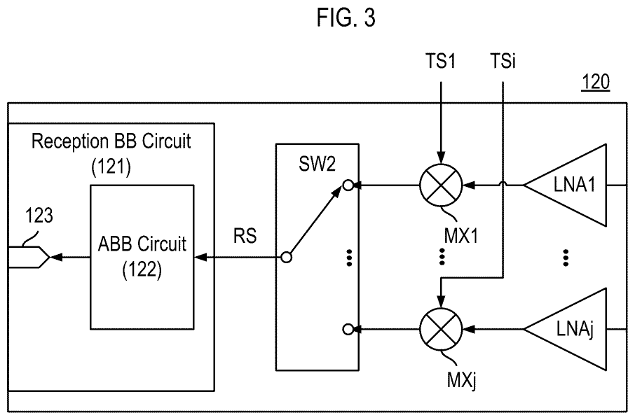

FIG. 3 is a diagram illustrating a switch-based reception circuit according to one or more embodiments.

Referring to FIG. 3, a reception circuit 120 according to one or more embodiments may be one of the reception circuits 120 illustrated in FIGS. 1 and 2. The reception circuit 120 may include a plurality of low-noise amplifiers LNA1 to LNAj, a plurality of mixers MX1 to MXj, a second switch SW2, and a reception baseband circuit 121.

The plurality of low-noise amplifiers LNA1 to LNAj may be configured to amplify a plurality of receive signals with low noise. The plurality of low-noise amplifiers LNA1 to LNAj may be provided in a number equal to j, the number of reception paths (where j is a positive integer). For example, when the plurality of transmit signals TS1 to TSi are radar signals, the plurality of receive signals may be reflected from a target.

The plurality of mixers MX1 to MXj may be coupled to a plurality of transmission paths and a plurality of reception paths. The plurality of mixers MX1 to MXj may receive a plurality of transmit signals TS1 to TSi through the plurality of transmission paths and a plurality of receive signals through the plurality of reception paths. The plurality of transmit signals TS1 to TSi may have multiplied frequencies according to the above-described embodiments (see FIGS. 1 and 2).

The plurality of mixers MX1 to MXj may perform frequency down-conversion on the plurality of receive signals based on the plurality of transmit signals TS1 to TSi corresponding to the plurality of transmission paths. The frequency down-converted receive signals may include information related to the target.

The second switch SW2 may include a single third pole and a plurality of fourth poles coupled to the plurality of mixers MX1 to MXj. The number of the plurality of fourth poles is j. The second switch SW2 may couple the single third pole to one of the plurality of fourth poles based on switching. The switching enables one of the plurality of frequency down-converted received signals RS to be provided to the reception baseband circuit 121.

The reception baseband circuit 121 may be configured to process a single receive signal RS corresponding to a single fourth pole coupled to a single third pole through switching at baseband. In one or more embodiments, the reception baseband circuit 121 may include an analog baseband circuit 122 and an analog-to-digital converter (ADC) 123. The analog baseband circuit 122 may be configured to perform at least one of signal amplification and gain adjustment, buffering, filtering, power distribution, or providing in-phase/quadrature (I/Q) paths, on the receive signal RS.

The ADC 123 may convert the receive signal, processed through the analog baseband circuit 122, into a digital domain based on a sampling frequency. The ADC 123 included in the reception circuit 120 of FIG. 3 may be shared across all reception paths. Accordingly, when the sampling frequency is fixed (or set to a specific value), the same sampling frequency may be applied to all receive signals.

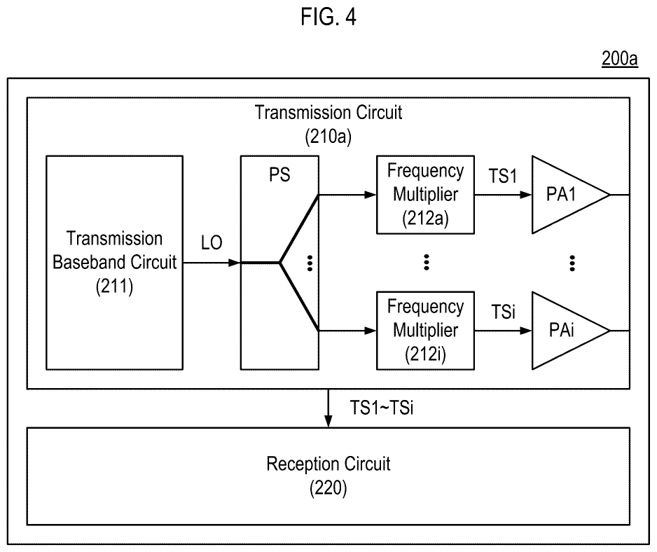

FIG. 4 is a diagram illustrating a power distribution-based RF chip according to one or more embodiments.

Referring to FIG. 4, an RF chip 200a according to one or more embodiments may include a transmission circuit 210a and a reception circuit 220, and the transmission circuit 210a may include a transmission baseband circuit 211, a power splitter PS, a plurality of frequency multipliers 212a to 212i, and a plurality of power amplifiers PA1 to PAi.

Unlike the illustration of FIG. 1, in the RF chip 200a according to one or more embodiments, a power splitter PS may be coupled between the transmission baseband circuit 211 and the plurality of frequency multipliers 212a to 212i. For example, the power splitter PS may be coupled to a single transmission path and a plurality of transmission paths.

The transmission baseband circuit 211 may obtain an LO signal LO based on phase locking and provide the LO signal LO to the power splitter PS through a single transmission path.

The power splitter PS may perform power distribution from a single transmission path to a plurality of transmission paths. In one or more embodiments, the power splitter PS may receive a single LO signal LO from a single transmission path and distribute the LO signal LO to the plurality of transmission paths. The distribution may result in each transmission path being provided with a transmission signal having distributed power, and with phases that may be either identical or different. According to various embodiments, the power splitter PS may include a Wilkinson divider, a resistive divider, or the like.

The plurality of frequency multipliers 212a to 212i may receive a plurality of transmit signals TS1 to TSi distributed from the power splitter PS and perform frequency multiplication based on a multiplication factor assigned to each of the plurality of frequency multipliers 212a to 212i. According to one or more embodiments, a plurality of frequency-multiplied transmit signals TS1 to TSi having different center frequencies and bandwidths may be provided through frequency multipliers having different assigned multiplication factors.

The plurality of power amplifiers PA1 to PAi may be coupled to the plurality of frequency multipliers 212a to 212i to perform power amplification on the frequency-multiplied transmit signals TS1 to TSi.

Unlike a switch, the power splitter PS may provide a plurality of transmit signals from a single LO signal LO to the plurality of frequency multipliers 212a to 212i in parallel (or simultaneously). Accordingly, the plurality of frequency multipliers 212a to 212i and the plurality of power amplifiers PA1 to PAi may process the plurality of transmit signals TS1 to TSi in parallel (or simultaneously).

The reception circuit 220 may receive a plurality of transmit signals TS1 to TSi from the transmission circuit 210a and perform frequency down-conversion on a plurality of receive signals based on the plurality of transmit signals TS1 to TSi. Similarly to the transmission circuit 210a, the reception circuit 220 may process the plurality of receive signals in parallel. Accordingly, the reception circuit 220 may simultaneously obtain signals reflected from each frequency band.

The RF chip 200a according to the above-described embodiments may distribute a plurality of transmit signals TS1 to TSi from a single LO signal LO through power distribution and process the distributed plurality of transmit signals TS1 to TSi in parallel. Accordingly, the RF chip 200a enables antennas, connected to the RF chip 200a, to transmit the transmit signals simultaneously without time division. Additionally, the RF chip 200a may support various bandwidths using only a single LO signal LO without modifying configurations related to the LO signal LO.

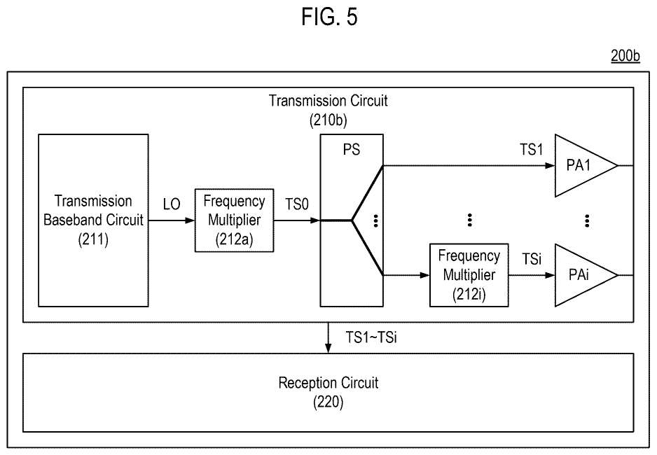

FIG. 5 is a diagram illustrating a power distribution-based RF chip including a frequency multiplier configured in a single transmission path according to one or more embodiments.

Referring to FIG. 5, an RF chip 200b according to one or more embodiments may include a transmission circuit 210b and a reception circuit 220, and the transmission circuit 210b may include a first frequency multiplier 212a configured in a single transmission path and at least one frequency multiplier configured in a plurality of transmission paths.

The first frequency multiplier 212a may be configured in a single transmission path, and may perform frequency multiplication on an LO frequency based on a multiplication factor. The first frequency multiplier 212a may output a frequency-multiplied transmit signal TS0 to a power splitter PS. Unlike the illustration of FIG. 4, the power splitter PS may distribute the transmit signal TS0 having a multiplied frequency up-converted from the LO frequency to the plurality of transmission paths.

In contrast to the RF chip 200b of FIG. 4, which includes a frequency multiplier configured for each transmission path, the RF chip 200b of FIG. 5 may include at least one frequency multiplier configured in a plurality of transmission paths. Accordingly, a frequency multiplier may not be configured in at least one transmission path among the plurality of transmission paths. For example, a frequency multiplier is not configured in the first transmission path in which the first power amplifier PA1 is configured, so that the first power amplifier PA1 may directly amplify the transmit signal distributed from the power splitter PS. An ith transmission path, in which the ith power amplifier PAi is configured, may include a second frequency multiplier 212i. The second frequency multiplier 212i may perform frequency multiplication on the transmit signal distributed through the power splitter PS based on a multiplication factor.

The reception circuit 220 may receive a plurality of transmit signals TS1 to TSi from the plurality of transmission paths and perform frequency down-conversion on a plurality of receive signals based on the plurality of transmit signals TS1 to TSi.

The RF chip 200b according to the above-described embodiments enables antennas, connected to the RF chip 200b, to simultaneously transmit the transmit signals without time division. Additionally, the RF chip 200b may support various bandwidths using only a single LO signal LO without modifying configurations related to the LO signal LO.

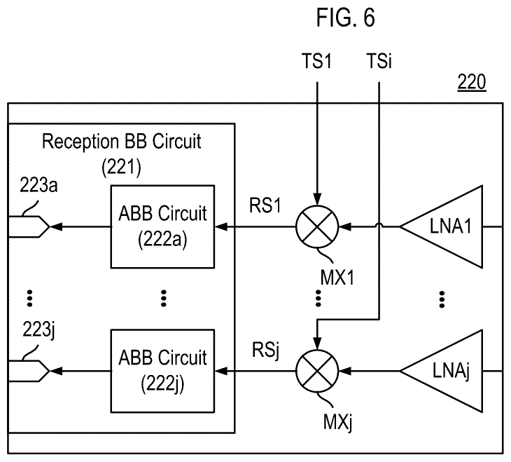

FIG. 6 is a diagram illustrating a reception circuit according to one or more embodiments.

Referring to FIG. 6, a reception circuit 220 according to one or more embodiments may be one of the reception circuits 220 illustrated in FIGS. 4 and 5. The reception circuit 220 may include a plurality of low-noise amplifiers LNA1 to LNAj, a plurality of mixers MX1 to MXj, and a reception baseband circuit 221.

The plurality of low-noise amplifiers LNA1 to LNAj may be configured to amplify a plurality of receive signals with low noise.

The plurality of mixers MX1 to MXj may receive a plurality of transmit signals TS1 to TSi through a plurality of transmission paths and a plurality of receive signals through a plurality of reception paths. The plurality of transmit signals TS1 to TSi may have multiplied frequencies according to the above-described embodiments (see FIGS. 4 and 5). The plurality of mixers MX1 to MXj may perform frequency down-conversion on the plurality of receive signals based on the plurality of transmit signals TS1 to TSi corresponding to the plurality of transmission paths. The plurality of receive signals RS1 to RSj, having down-converted frequencies, may be provided to the reception baseband circuit 221.

The reception baseband circuit 221 may be configured to process the plurality of receive signals RS1 to RSj in parallel at baseband. In one or more embodiments, the reception baseband circuit 221 may include a plurality of analog baseband circuits 222a to 222j and a plurality of ADCs 223a to 223j. The analog baseband circuits may be provided in a number equal to j, the number of reception paths, and the ADCs may similarly be provided in a number equal to j.

Each of the plurality of analog baseband circuits 222a to 222j may be configured to perform at least one of signal amplification and gain adjustment, buffering, filtering, power distribution, or providing I/Q paths, on a receive signal. Each of the plurality of ADCs 223a to 223j may convert the receive signal, processed through the analog baseband circuit, into a digital domain. For example, the first analog baseband circuit 222a may process a frequency down-converted receive signal from the first mixer MX1 at baseband, and the first ADC 223a may convert the processed receive signal into the digital domain.

The configurations of the reception circuit 220 according to the above-described embodiments may be mapped to one of the plurality of reception paths. For example, the first low-noise amplifier LNA1, the first mixer MX1, the first analog baseband circuit 222a, and the first ADC 223a may be mapped to the first transmission path. According to one or more embodiments, similarly to the plurality of transmission paths, the plurality of reception paths may also process receive signals of different bands.

In one or more embodiments, the plurality of ADCs 223a to 223j may perform analog-to-digital conversion based on the same sampling frequency or different sampling frequencies. When the sampling frequencies for the plurality of ADCs 223a to 223j are different, different sampling frequencies may be applied for different bands.

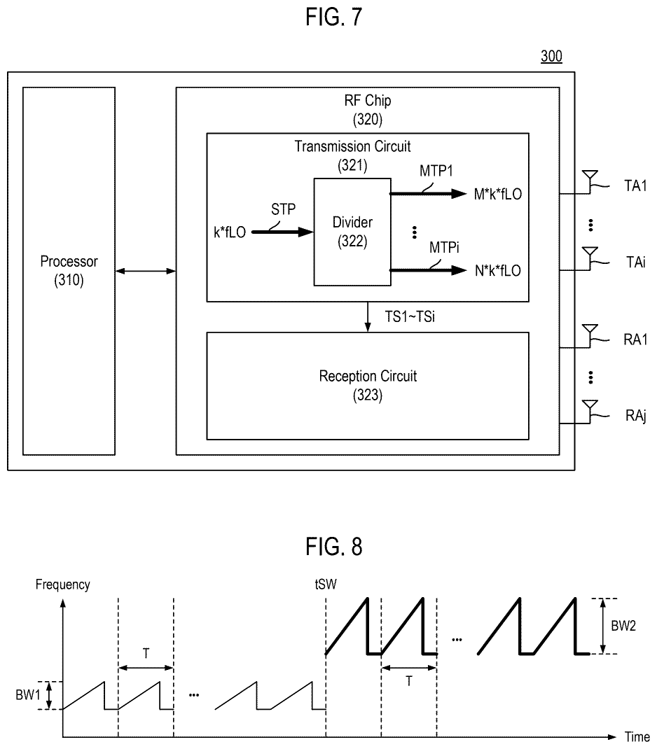

FIG. 7 is a diagram illustrating a transceiver according to one or more embodiments.

Referring to FIG. 7, a transceiver 300 according to one or more embodiments may include a processor 310, an RF chip 320, a plurality of transmission antennas, and a plurality of reception antennas.

The processor 310 may be configured to process a digital signal. The digital signal may be a baseband signal. For example, the processor 310 may obtain, generate, or process a digital signal corresponding to a transmit signal and provide the digital signal to the RF chip 320. Alternatively, the processor 310 may receive a digital signal corresponding to a receive signal from the RF chip 320 and process the digital signal to obtain information.

In one or more embodiments, the processor 310 may process the digital signal based on fast Fourier transform (FFT), short-time Fourier transform (STFT), 2D and/or 3D FFT.

In one or more embodiments, the processor 310 may detect a target through constant false alarm rate (CFAR) processing on a digital signal corresponding to a receive signal. CFAR is an algorithm designed to maintain a constant false alarm rate for target detection, even when no reflected signal is present but a reflection is falsely detected due to varying noise levels caused by a change in the surrounding environment. CFAR may be used to detect a target from a receive signal based on a noise level and a threshold corresponding to the surrounding environment.

In one or more embodiments, the processor 310 may obtain various types of information based on a plurality of transmit signals and a plurality of receive signals. For example, the processor 310 may calculate range information to a target based on a frequency difference (for example, a beat frequency) between the transmit signal and the received signal, calculate angle information to the target based on a phase difference between the transmit signal and the received signal, or calculate velocity information of the target based on the Doppler effect.

The RF chip 320 may be configured to obtain a plurality of transmit signals from a digital signal or to obtain a baseband signal from a plurality of receive signals corresponding to a plurality of transmit signals reflected from a target. According to various embodiments, the RF chip 320, the transmission circuit 321, the divider 322, and the reception circuit 323 may be configured based on FIG. 1 to FIG. 6 described above. For example, when the RF chip 320 is configured based on switching, the divider 322 may be a first switch (see FIGS. 1 and 2). For example, when the RF chip 320 is configured based on power distribution, the divider 322 may be a power splitter (see FIGS. 4 and 5).

In one or more embodiments, the RF chip 320 may obtain a first transmit signal having a frequency, equal to the LO frequency or a first frequency multiplied from the LO frequency from a digital signal and distribute the first transmit signal from a single transmission path STP to a plurality of transmission paths MTP1 to MTPi. For example, when the RF chip 320 is configured based on switching (see FIGS. 1 and 2), the RF chip 320 may couple a single transmission path STP to a single transmission path through the divider 322. For example, when the RF chip 320 is configured based on power distribution (see FIGS. 4 and 5), the RF chip 320 may perform power distribution from the single transmission path STP to the plurality of transmission paths MTP1 to MTPi through the divider 322.

The RF chip 320 may output a second transmit signal based on frequency multiplication and power amplification for at least one of the plurality of transmission paths MTP1 to MTPi. According to one or more embodiments, frequency multiplication may not be performed on at least one of the plurality of transmission paths MTP1 to MTPi (see FIGS. 2 and 5).

In one or more embodiments, the RF chip 320 may perform frequency multiplication on a first transmission path, among the plurality of transmission paths MTP1 to MTPi, based on a first multiplication factor and perform frequency multiplication on a second transmission path, among the plurality of transmission paths MTP1 to MTPi, based on a second multiplication factor greater than the first multiplication factor.

A plurality of transmission antennas TA1 to TAm may be configured to transmit the second transmit signal, and a plurality of reception antennas RA1 to RAn may be configured to receive the receive signals corresponding to the second transmit signal reflected from a target.

FIG. 8 is a waveform diagram illustrating a transmission operation of the transceiver according to one or more embodiments. For clarity, an example is provided where a transmit signal is a frequency-modulated continuous wave (FMCW) signal, but the embodiments are not limited thereto.

Referring to FIGS. 7 and 8, a time interval before a switching time point tSW may be defined as a period during which the transceiver 300 operates in a first mode, and a time interval after the switching time point tSW may be defined as a period during which the transceiver 300 operates in a second mode. The first mode is defined as a mode in which the transceiver 300 operates at a low frequency, and the second mode is defined as a mode in which the transceiver 300 operates at a high frequency and does not overlap the first mode in a time domain.

For an arbitrary bandwidth BW, a distance resolution indicating the degree (or resolution) to which the transceiver 300 may detect a distance to a target may be defined by the following Equation 1.

$$Δ R = \frac{c}{2 B W} , \qquad Equation 1$$

where ΔR is a range resolution, and c is a propagation speed of wave (for example, a speed of light). For example, the range resolution is inversely proportional to the bandwidth BW (or time-frequency slope of a transmit signal) and decreases as the bandwidth BW increases. Accordingly, the performance of the range resolution at a larger bandwidth BW may be further improved.

The maximum detection range of the transceiver 300 may be defined by the following Equation 2.

$${R}_{max} = Δ {RTF}_{s} , \qquad Equation 2$$

where Rₘₐₓ is a maximum detection range, T is a period of the transmit signal, and F_{S} is a sampling frequency. For example, in FIG. 8, the transmit signal is a chirp signal, and Tis a period of a single chirp signal. The sampling frequency is a sampling frequency of an ADC included in the receive signal according to the above-described embodiments. For example, the greater the bandwidth BW, the period of the transmitted signal, and/or the sampling frequency, the greater the maximum detection range.

When the period of the transmit signal and the sampling frequency are the same for the transmission paths, a target disposed at long range may be detected in the first mode of the low-frequency band with relatively high range resolution. In contrast, a target disposed at short range may be detected in the second mode of a high frequency may detect a target located at a relatively short distance with a relatively small range resolution (for example, improved range resolution performance). The period of the transmit signal is the same for all transmission paths when the transmit signal is provided from a single transmission path STP according to the above-described embodiments.

When the first multiplication factor assigned to the frequency multiplier corresponding to the first transmission path is smaller than the second multiplication factor assigned to the frequency multiplier corresponding to the second transmission path, the processor 310 may control the first switch to activate the first transmission path in the first mode. The first switch may couple a single first pole to a single second pole corresponding to the first transmission path (or couple the single transmission path STP to the first transmission path). Accordingly, the transceiver 300 may detect a target in a low-frequency band by multiplying the transmit signal based on a smaller first multiplication factor.

In the first mode, the transceiver 300 may detect a target at a relatively long range with a coarse range resolution and obtains range information. A transmit signal transmitted in the first mode may have a small bandwidth BW1, as illustrated in the drawing.

The processor 310 may control the first switch to activate the second transmission path in the second mode. The first switch may couple a single first pole to a single first pole corresponding to the second transmission path (or couple the single transmission path STP to the second transmission path). Accordingly, the transceiver 300 may detect a target in a high-frequency band by multiplying the transmit signal based on a larger second multiplication factor.

In the second mode, the transceiver 300 may detect a target at a relatively short range with a fine range resolution and obtain range information. A transmit signal transmitted in the second mode may have a larger bandwidth BW2 than BW1, as illustrated in the drawing.

According to one or more embodiments, the RF chip 320 may include a third transmission path in which a power amplifier directly coupled to the divider 322 is configured (see FIGS. 2 and 5). In the first mode in which the RF chip 320 operates at a low frequency, the processor 310 may control the first switch to couple a single first pole to a single second pole corresponding to the third transmission path. Alternatively, in the second mode in which the RF chip 320 operates at a high frequency, the processor 310 may control the first switch to couple a single first pole to a single second pole corresponding to the first transmission path. Accordingly, the bandwidth BW1 of the transmit signal provided through the third transmission path, where a frequency multiplier is omitted, may be smaller than the bandwidth BW2 of the transmit signal provided through the first transmission path.

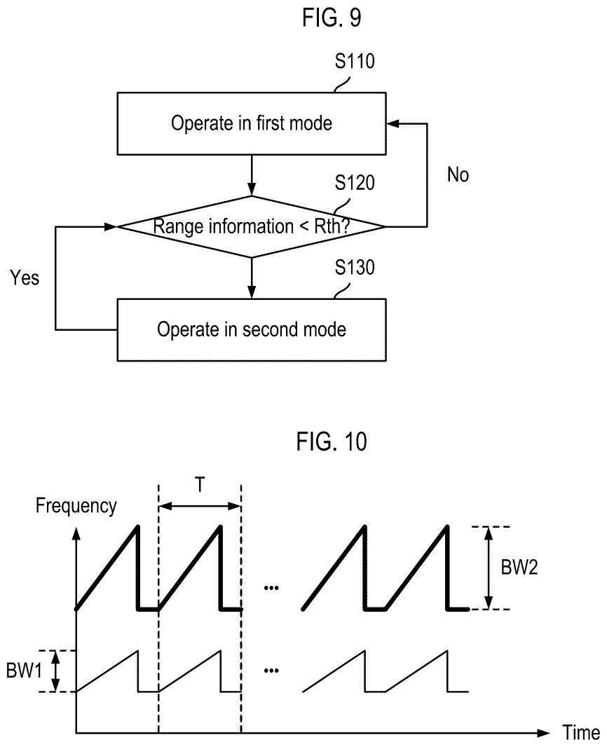

FIG. 9 is a flowchart illustrating a method of operating a transceiver according to one or more embodiments.

Referring to FIG. 9, in operation S110, the transceiver may operate in a first mode. For example, the transceiver may operate in the first mode when initially detecting a target. The first mode may be set as an initial operating mode when the transceiver starts a detection operation. During the first mode, the transceiver may transmit a transmit signal in a low-frequency band, detect a target through a reflected received signal, and obtain range information on the target.

In operation S120, the transceiver may compare the range information, obtained in operation S110, with a specific value. The specific value is a predetermined or defined threshold for the range information, which may be set or modified through a processor.

When the range information is determined to be greater than or equal to the specific value in operation S120, the transceiver may be maintained in the first mode. For example, when the target is at a relatively long distance, the transceiver may continue to detect the target in the low-frequency band.

Alternatively, when the range information is determined to be less than the specific value in operation S120, the flow proceeds to operation S130, in which the transceiver may switch from the first mode to a second mode, and operate in the second mode. For example, when the target, initially at a long distance, approaches within the specific value, the transceiver may operate in the second mode, which facilitates detection at a relatively short range.

The transceiver may perform operation S120 again in the second mode. For example, the transceiver may obtain range information based on the receive signal received in the second mode. When the range information in the second mode is greater than or equal to the specific value, the transceiver may switch from the second mode to the first mode and perform operation S110 again. Alternatively, when the range information in the second mode is less than the specific value, the transceiver be maintained in the second mode.

The above-described operations S110 to S130 may be performed through the processor included in the transceiver.

FIG. 10 is a waveform diagram illustrating a transmission operation of the transceiver according to one or more embodiments.

Referring to FIG. 10, the transceiver according to one or more embodiments may transmit signals of different bands simultaneously without time division through power distribution. Unlike FIG. 8 where signals of different bands are transmitted in different time intervals based on switching time points, FIG. 10 illustrates that the transceiver may transmit signals of different bands in the same time interval. As illustrated in FIG. 10, a transmit signal having bandwidth BW1 and a transmit signal having bandwidth BW2 may be transmitted in the same time interval. Similarly to FIG. 8, when transmit signals are provided through a single transmission path, the transmit signals may have the same period.

According to various embodiments, the transceiver may multiply an LO frequency, distribute the power of a transmit signal having the multiplied frequency, and transmit signals of different bands in the same time interval through frequency multiplication of the distributed transmit signals. Alternatively, the transceiver may distribute the power of a transmit signal having the LO frequency and transmit the transmit signals of different bands in the same time interval through frequency multiplication of the distributed transmit signals.

The transmission operation according to the above-described embodiments enables efficient utilization of time resources for signal transmission.

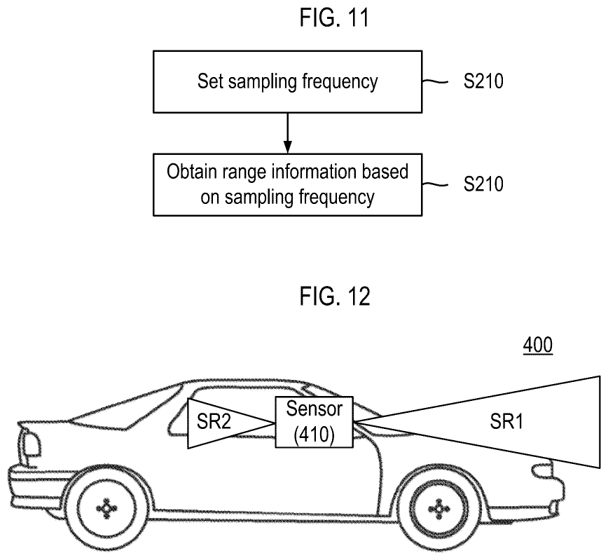

FIG. 11 is a flowchart illustrating a method of operating a transceiver according to one or more embodiments.

Referring to FIG. 11, in operation S210, the transceiver may set a sampling frequency differently for each reception path.

In one or more embodiments, when a first reception path is assigned to a relatively low-frequency band and a second reception path is assigned to a relatively high-frequency band, the transceiver may decrease a sampling frequency of the ADC configured in the second reception path below a set value to detect a target at an ultra-short range. A maximum detection range may be reduced (see Equation 1 and Equation 2) while maintaining a range resolution of the transceiver for a receive signal provided from the second reception path.

Alternatively, the transceiver may increase the sampling frequency of the ADC configured in the first reception path above a set value. A maximum detection range may be increased (see Equation 1 and Equation 2) while maintaining the range resolution of the transceiver for the receive signal provided from the first reception path.

In operation S220, the transceiver may convert the receive signal into a digital domain based on the sampling frequency set in operation S210 and obtain range information from the digital signal.

The operation method according to the above-described embodiments may allow a transceiver having a plurality of reception paths to flexibly adjust the detection range for each reception path.

FIG. 12 is a diagram illustrating a vehicle according to one or more embodiments.

Referring to FIG. 12, a vehicle 400 according to one or more embodiments may include a sensor 410 and may further include other components for the operation and driving of the vehicle 400.

The sensor 410 may include the transceiver according to the above-described embodiments or be configured to perform the operation(s) of the transceiver (see FIGS. 1-11). The sensor 410 may detect objects within a first sensing range SR1 and a second sensing range SR2. For example, the first sensing range SR1 is defined, from the perspective of the vehicle 400, as a region external to the vehicle 400 that may require detection of relatively distant objects for driving and operational purposes. Accordingly, the sensor 410 may obtain a transmit signal in a low-frequency band and transmit the obtained transmit signal to the first sensing range SR1. For operation in the low-frequency band, the sensor 410 may operate in the first mode according to the above-described embodiments.

The second sensing range SR2 is defined, from the perspective of the vehicle 400, as a region internal to the vehicle 400 to detect objects present inside the vehicle 400. Accordingly, detection of objects at a relatively short range may be required for the second sensing range SR2, so that the sensor 410 may obtain a transmit signal in a high-frequency band and transmit the obtained transmit signal to the second sensing range SR2. For operation in the high-frequency band, the sensor 410 may operate in the second mode according to the above-described embodiments.

As set forth above, according to embodiments, a multiple-band RF chip configured to cover multiple bands with a single LO signal and a transceiver including the multiple-band RF chip may be provided.

While various embodiments have been shown and described above, it will be apparent to those skilled in the art that modifications and variations could be made without departing from the scope of the present inventive concept as defined by the appended claims.

What is claimed is:

1. A radio-frequency (RF) chip comprising:
a first switch comprising a single first pole coupled to a single transmission path provided with a local oscillator (LO) signal and a plurality of second poles coupled to a plurality of transmission paths, the first switch configured to couple the single first pole to one of the plurality of second poles based on switching;
a first frequency multiplier coupled to a first transmission path among the plurality of transmission paths, the first frequency multiplier configured to perform frequency multiplication based on a first multiplication factor; and
a first power amplifier coupled to the first frequency multiplier.

2. The RF chip of claim 1, further comprising:
a second frequency multiplier coupled to a second transmission path among the plurality of transmission paths, the second frequency multiplier configured to perform frequency multiplication based on a second multiplication factor; and
a second power amplifier coupled to the second frequency multiplier.

3. The RF chip of claim 1, further comprising:
a transmission baseband circuit configured to obtain the LO signal based on phase locking to an LO frequency and to provide the LO signal to the first switch.

4. The RF chip of claim 3, further comprising:
a third frequency multiplier configured in the single transmission path, the third frequency multiplier configured to perform frequency multiplication on the LO frequency based on a third multiplication factor and to output a frequency-multiplied transmit signal to the single first pole.

5. The RF chip of claim 4, wherein:
the first frequency multiplier is configured to perform frequency multiplication on the frequency-multiplied transmit signal based on the first multiplication factor.

6. The RF chip of claim 2, wherein:
the second multiplication factor is greater than the first multiplication factor;
the first switch is configured to couple the single first pole to the one of the plurality of second poles corresponding to the first transmission path in a first mode operating at a low frequency; and
the first switch is configured to couple the single first pole to the one of the plurality of second poles corresponding to the second transmission path in a second mode operating at a high frequency.

7. The RF chip of claim 4, further comprising:
a third power amplifier configured in a third transmission path among the plurality of transmission paths, the third power amplifier configured to amplify the frequency-multiplied transmit signal.

8. The RF chip of claim 7, wherein:
the first switch is configured to couple the single first pole to the one of the plurality of second poles corresponding to the third transmission path in a first mode operating at a low frequency; and
the first switch is configured to couple the single first pole to the one of the plurality of second poles corresponding to the first transmission path in a second mode operating at a high frequency.

9. The RF chip of claim 1, further comprising:
a plurality of low-noise amplifiers configured to amplify a plurality of receive signals with low noise;
a plurality of mixers coupled to the plurality of transmission paths, the plurality of mixers configured to perform frequency down-conversion on the plurality of receive signals based on a plurality of transmit signals corresponding to the plurality of transmission paths;
a second switch comprising a single third pole and a plurality of fourth poles coupled to the plurality of mixers, the second switch configured to couple the single third pole to one of the plurality of fourth poles based on switching; and
a reception baseband circuit configured to process a single receive signal, among the plurality of receive signals, corresponding to the one of the plurality of fourth poles that is coupled to the single third pole, in baseband.

10. A radio-frequency (RF) chip comprising:
a power splitter coupled to a single transmission path provided with a local oscillator (LO) signal and to a plurality of transmission paths, the power splitter configured to perform power distribution from the single transmission path to the plurality of transmission paths;
a first frequency multiplier coupled to a first transmission path among the plurality of transmission paths, the first frequency multiplier configured to perform frequency multiplication based on a first multiplication factor; and
a first power amplifier coupled to the first frequency multiplier.

11. The RF chip of claim 10, further comprising:
a second frequency multiplier coupled to a second transmission path among the plurality of transmission paths, the second frequency multiplier configured to perform frequency multiplication based on a second multiplication factor; and
a second power amplifier coupled to the second frequency multiplier.

12. The RF chip of claim 10, further comprising:
a transmission baseband circuit configured to obtain the LO signal based on phase locking to an LO frequency and to provide the LO signal to the power splitter; and
a third frequency multiplier configured in the single transmission path, the third frequency multiplier configured to perform frequency multiplication on the LO frequency based on a third multiplication factor and to output a frequency-multiplied transmit signal to the power splitter.

13. The RF chip of claim 11, wherein:
the second multiplication factor is greater than the first multiplication factor.

14. The RF chip of claim 12, further comprising:
a third power amplifier configured in a third transmission path among the plurality of transmission paths, the third power amplifier configured to amplify the frequency-multiplied transmit signal.

15. A transceiver comprising:
a processor configured to process a digital signal;
a radio-frequency (RF) chip configured to obtain a first transmit signal having a frequency equal to or multiplied from a local oscillator (LO) frequency based on the digital signal, to distribute the first transmit signal from a single transmission path to a plurality of transmission paths, and to output a second transmit signal based on frequency multiplication and power amplification for at least one of the plurality of transmission paths; and
a plurality of antennas configured to transmit the second transmit signal.

16. The transceiver of claim 15, wherein:
the RF chip is configured to couple the single transmission path to one of the plurality of transmission paths based on switching.

17. The transceiver of claim 15, wherein:
the RF chip is configured to perform power distribution from the single transmission path to the plurality of transmission paths.

18. The transceiver of claim 16, wherein:
the RF chip is configured to perform frequency multiplication on a first transmission path, among the plurality of transmission paths, based on a first multiplication factor and to perform frequency multiplication on a second transmission path, among the plurality of transmission paths, based on a second multiplication factor greater than the first multiplication factor; and
the processor is configured to control the switching to couple the single transmission path to the first transmission path in a first mode operating at a low frequency and to couple the single transmission path to the second transmission path in a second mode operating at a high frequency and not overlapping the first mode in a time domain.

19. The transceiver of claim 18, wherein:
the plurality of antennas is configured to receive a receive signal corresponding to the second transmit signal reflected from a target; and
the processor is configured to obtain range information on the target based on the receive signal in the first mode, to switch from the first mode to the second mode when the range information is less than a specific value, and to switch from the second mode to the first mode when the range information is greater than or equal to the specific value in the second mode.

20. The transceiver of claim 17, wherein:
the plurality of antennas is configured to receive a receive signal corresponding to the second transmit signal reflected from a target;
the RF chip is configured to process the receive signal through a plurality of reception paths corresponding to the plurality of transmission paths; and
the processing the digital signal comprises converting the receive signal to a digital domain based on sampling frequencies set differently for each of the plurality of reception paths.
